(19) United States
(12) Patent Application Publication
(10) Pub. No.: US 2013/0163345 A1
(43) Pub. Date: Jun. 27, 2013

(54) SEMICONDUCTOR MEMORY DEVICE AND METHOD OF OPERATING THE SAME

(71) Applicants: Sang Tae AHN, Seoul (KR); Gyu Seog Cho, Gyeonggi-do (KR); Chae Moon Lim, Gyeonggi-do (KR); Yoo Nam Jeon, Gyeonggi-do (KR); Seung Hwan Baik, Gyeonggi-do (KR); Hee Jin Lee, Gyeonggi-do (KR); Jae Seok Kim, Seoul (KR); Kyung Sik Mun, Gyeonggi-do (KR); U Seon Im, Gyeonggi-do (KR)

(72) Inventors: Sang Tae AHN, Seoul (KR); Gyu Seog Cho, Gyeonggi-do (KR); Chae Moon Lim, Gyeonggi-do (KR); Yoo Nam Jeon, Gyeonggi-do (KR); Seung Hwan Baik, Gyeonggi-do (KR); Hee Jin Lee, Gyeonggi-do (KR); Jae Seok Kim, Seoul (KR); Kyung Sik Mun, Gyeonggi-do (KR); U Seon Im, Gyeonggi-do (KR)

(21) Appl. No.: 13/605,552

(22) Filed: Sep. 6, 2012

(30) Foreign Application Priority Data
Dec. 21, 2011 (KR) 10-2011-0139049

(51) Int. Cl. G11C 16/12; G11C 16/04

(52) U.S. Cl. 365/185.23

(57) ABSTRACT

A method of operating a semiconductor memory device includes an operation of applying a first voltage to selected bit lines, a second voltage to unselected bit lines and a common source line, and turning on drain and source selection transistors, an operation of applying a program voltage to a selected word line and a switch voltage to a switch word line, and applying a first pass voltage to first unselected word lines disposed between the switch word line and a common source line and between the selected word line and a bit line, and elevating the switch voltage to generate hot electrons and inject the hot electrons to a selected memory cell of the selected word line to program the selected cell.

### CROSS-REFERENCE TO RELATED APPLICATION

This application claims priority to Korean Patent Application No. 10-2011-0139049, filed on Dec. 21, 2011, the disclosure of which is incorporated herein by reference in its entirety.

### BACKGROUND

The present invention relates to a semiconductor memory device and a method of operating the same. More specifically, the present invention relates to a nonvolatile memory device and a method of operating the same.

In a NAND memory device, electrons are injected through a tunnel insulating layer into a floating gate by Fowler-Nordheim (FN) tunneling during a program operation. To perform the program operation using FN tunneling, a high voltage is to be applied to a selected word line (or control gate). Due to the use of the high voltage, the amount of a leakage current may increase, and program characteristics may be changed depending on the increasing amount of the leakage current, thereby increasing power consumption.

### SUMMARY OF THE INVENTION

The present invention is directed to a semiconductor memory device, which performs a program operation using a hot carrier injection (HCI) technique, and a method of operating the same.

One aspect of the present invention provides a method of operating a semiconductor memory device, which includes at least one memory string coupled between a bit line and a common source line and including a drain selection transistor and a source selection transistor coupled to the bit line and the common source line, respectively, and a plurality of memory cell coupled in series between the drain and source selection transistors, the method including: supplying first and second voltages to the memory string through the bit line and the common source line, respectively, by turning on the drain and source selection transistors; applying a program voltage to a selected word line of word lines coupled to the memory cells and a switch voltage to a switch word line disposed between the selected word line and the common source line; applying a first pass voltage to first unselected word lines disposed between the switch word line and the common source line and between the selected word line and the bit line and a second pass voltage lower than the first pass voltage to a second unselected word line between the switch word line and the selected word line; and elevating the switch voltage to generate hot electrons and inject the hot electrons into a selected memory cell of the selected word line, among the memory cells.

Another aspect of the present invention provides a method of operating a semiconductor memory device, which includes a plurality of memory strings coupled between respective bit lines and a common source line and each including a drain selection transistor and a source selection transistor coupled to the bit line and the common source line, respectively, and a plurality of memory cell coupled in series between the drain and source selection transistors, the method including: applying a first voltage to selected bit lines of the bit lines and a second voltage to unselected bit lines other than the selected bit lines and the common source line; turning on the drain and source selection transistors; applying a program voltage to a selected word line of word lines coupled to the memory cells and a switch voltage to a switch word line disposed between the selected word line and the bit line; applying a first pass voltage to first unselected word lines disposed between the switch word line and the bit line and between the selected word line and the common source line; and elevating the switch voltage to generate hot electrons and inject the hot electrons to a selected memory cell of the selected word line, among the memory cell, to program the selected cell.

When the first pass voltage is applied, a second pass voltage lower than the first pass voltage may be applied to a second unselected word line between the switch word line and the selected word line.

A third pass voltage lower than the first pass voltage and higher than the second pass voltage may be applied to a third unselected line disposed adjacent to the selected word line and between the selected word line and the common source line, out of the first unselected word lines.

A fourth pass voltage lower than the first pass voltage and higher than the third pass voltage may be applied to a fourth unselected line disposed adjacent to the third unselected line and between the third unselected line and the common source line, out of the first unselected lines.

Before the elevating of the switch voltage, the source selection transistors may turn off. The switch voltage may be elevated from a negative voltage to a first pass voltage.

Another aspect of the present invention provides a semiconductor memory device including: a plurality of memory strings connected between a common source line and respective bit lines and each including a drain selection transistor and a source selection transistor coupled to the bit line and the common source line, respectively, and a plurality of memory cells having control gates connected to respective word lines between the drain and source selection transistors; and a peripheral circuit configured to perform a first operation of applying a first voltage to selected bit lines of the bit lines and a second voltage to unselected bit lines other than the selected bit lines and the common source line and turning on the drain and source selection transistors, a second operation of applying a program voltage to a selected word line of the word lines, a switch voltage to a switch word line disposed adjacent to the selected word line, a first pass voltage to first unselected word lines other than the selected word line and the switch word line, and a third operation of elevating the switch voltage to generate hot electrons and inject the hot electrons to a selected cell of the selected word line, among the memory cells.

### BRIEF DESCRIPTION OF THE DRAWINGS

The above and other features and advantages of the present invention will become more apparent to those of ordinary skill in the art by describing in detail exemplary embodiments thereof with reference to the accompanying drawings in which:

FIG. 1 is a block diagram of a semiconductor memory device according to an exemplary embodiment of the present invention;

FIG. 2 is a circuit diagram of a memory block shown in FIG. 1;

FIGS. 3 through 6 are diagrams illustrating a program operation of the semiconductor memory device of FIG. 1, using a hot carrier injection (HCI) technique according to an exemplary embodiment of the present invention;

FIG. 7 is a signal waveform diagram illustrating a method of operating a semiconductor memory device according to an exemplary embodiment of the present invention;

FIG. 8 is a graph illustrating a variation in the voltage of a drain region during a program operation using an HCI technique according to an exemplary embodiment of the present invention;

FIG. 9 is a diagram illustrating a program operation of applying a ground voltage to a channel region of a program prohibition string in FIG. 8;

FIG. 10 is a diagram of a program operation of the semiconductor memory device of FIG. 1, using an HCI technique according to another embodiment of the present invention;

FIG. 11 is a cross-sectional view of a selected memory string configured to cause HCI out of memory strings shown in FIG. 10;

FIG. 12 is a cross-sectional view of an unselected memory string configured not to generate HCI out of the memory strings shown in FIG. 10; and

FIG. 13 is a signal waveform diagram illustrating a method of operating a semiconductor memory device according to another exemplary embodiment of the present invention.

### DETAILED DESCRIPTION OF EMBODIMENTS

The present invention will be described more fully hereinafter with reference to the accompanying drawings, in which exemplary embodiments of the present invention are shown. The present invention may, however, be embodied in different forms and not be limited to the embodiments set forth herein. Rather, these exemplary embodiments are provided to fully convey the scope of the present invention to one skilled in the art.

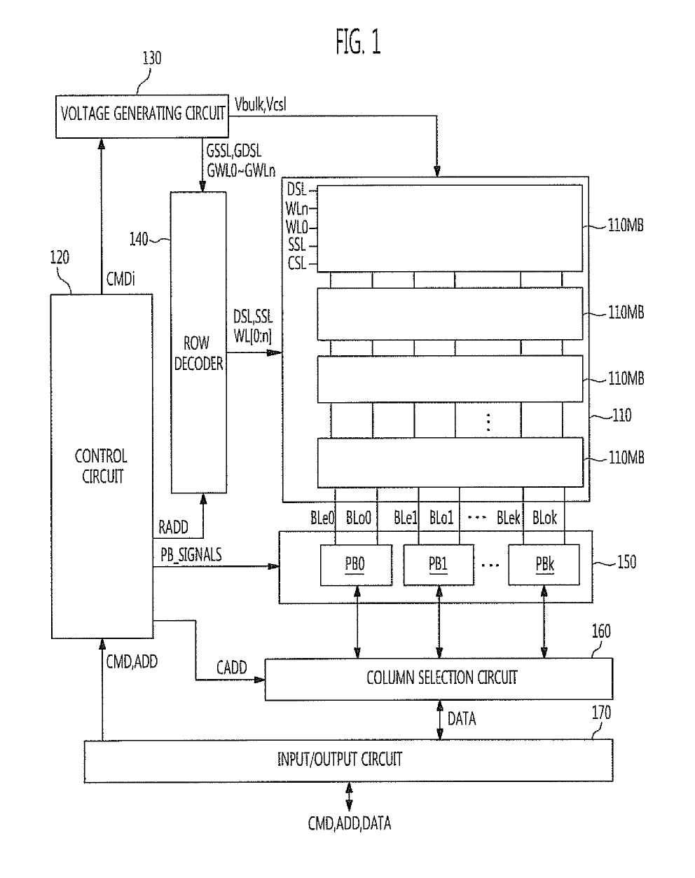

FIG. 1 is a circuit diagram of a semiconductor memory device according to an exemplary embodiment of the present invention.

Referring to FIG. 1, the semiconductor memory device may include a memory array 110 and peripheral circuits 120 to 170. The memory array 110 may include a plurality of memory cells, which may be grouped in memory blocks. In the case of a NAND flash memory device, the peripheral circuits 120 to 170 may include a control circuit 120, a voltage generating circuit 130, a row decoder 140, a page buffer group 150, a column selection circuit 160, and an input/output (I/O) circuit 170.

The voltage generating circuit 130 and the row decoder 140 may constitute a voltage supply circuit and provide operating voltages, used for a program operation, a read operation, or an erase operation, to local lines SSL, WL0 to WLn, and DSL of a selected memory block and a common source line CSL. That is, the voltages applied to the local lines SSL, WL0 to WLn, and DSL and the voltages applied to the common source line CSL may be voltages supplied from the voltage supply circuit 130 and 140 to perform a program operation, a read operation, or an erase operation under the control of the control circuit 120.

The page buffer group 150 may control or sense voltages of the bit lines BLe0 to BLek and BLo0 to Blok during data I/O operations. That is, voltages applied to the bit lines BLe0 to BLek and BLo0 to Blok may be voltages supplied from the page buffer group 150 to perform a program operation, an erase operation, or a read operation under the control of the control circuit 120.

The column selection circuit 160 serves to control transmission of data between the page buffer group 150 and the I/O circuit 170. The I/O circuit 170 may transmit an external input command signal CMD, an address signal ADD, and data DATA to internal circuits, such as the control circuit 120 or the page buffer group 150, or externally transmit data latched in the page buffer group 150 from the memory cells.

As described above, during program, read, and erase operations related with the input/output and erasure of data, the operating circuits 130 to 170 may be controlled by the control circuit 120. The above-described components will be described in further detail.

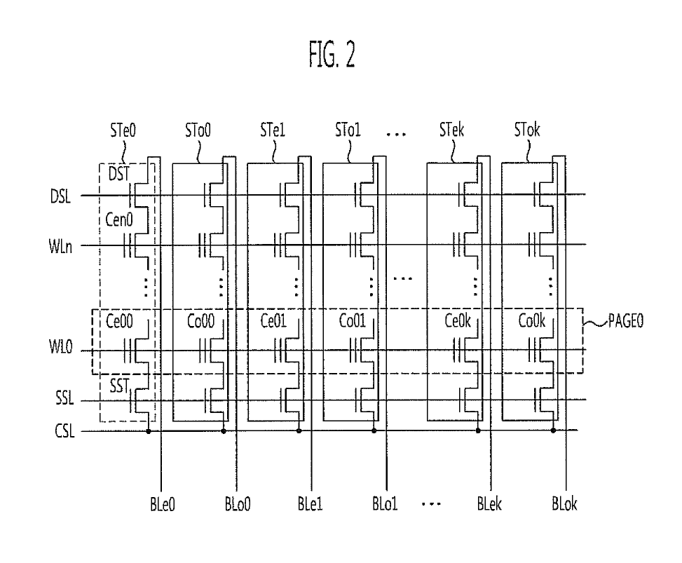

FIG. 2 is a circuit diagram of each of the memory blocks shown in FIG. 1.

Referring to FIG. 2, each of the memory blocks may include a plurality of strings STe0 to STek and STo0 to STok connected between bit lines BLe0 to BLek and BLo0 to Blok and the common source line CSL. That is, the strings STe0 to STek and STo0 to STok may be respectively connected to the corresponding bit lines BLe0 to BLek and BLo0 to Blok and connected in common to the common source line CSL. Each of the strings STe0 to STek and STo0 to STok, for example, the string Ste0 may include a source selection transistor SST having a source connected to the common source line CSL, a plurality of memory cells Ce00 to Cen0, and a drain select transistor DST having a drain connected to the corresponding one BLe0 of the bit lines BLe0 to BLek and BLo0 to Blok. The memory cells Ce00 to Cen0 may be connected in series between the source and drain selection transistors SST and DST. A gate of the source selection transistor SST may be connected to a source selection line SSL, gates of the memory cells Ce00 to Cen0 may be respectively connected to word lines WL0 to WLn, and a gate of the drain selection transistor DST may be connected to a drain selection line DSL.

In a NAND flash memory device, memory cells included in a memory cell block may be classified into physical pages or logic pages. For example, memory cells Ce00 to Ce0k and Co00 to Co0k connected to one word line (e.g., WL0) may constitute one physical page PAGE0. Also, even memory cells Ce00 to Ce0k connected to one word line (e.g., WL0) may constitute one even physical page, while odd memory cells Co00 to Co0k connected thereto may constitute one odd physical page. These pages (or the even page and odd page) may be a basic unit of a program operation or read operation. Also, the memory block may be a basic unit of an erase operation.

Referring to FIGS. 1 and 2, the control circuit 120 may output an internal command signal COMi for performing a program operation, a read operation, or an erase operation in response to a command signal COM externally input through the I/O circuit 170 and output PB control signals PB_SIGNALS for controlling page buffers PB0 to PBk included in the page buffer group 150 depending on the kind of an operation. Also, the control circuit 120 may output a row address signal RADD and a column address signal CADD in response to an address signal ADD externally input through the I/O circuit 170.

The voltage generating circuit 130 may output operating voltages used for the memory cells to perform a program operation, a read operation, or an erase operation to global lines GSSL, GWL0 to GWLn, and GDSL, in response to the internal command signal CMDi of the control circuit 120. Also, the voltage generating circuit 130 may apply a bulk voltage Vbulk to a bulk of a selected memory block and apply a common source voltage Vcsl to the common source line CSL.

The row decoder 140 may transmit operating voltages, which are output by the voltage generating circuit 130 to the global lines GSSL, GWN0 to GWLn, and GDSL, to local lines SSL, WN0 to WLn, and DSL of a selected memory block, out of memory blocks 110 MB of the memory array 110, in response to the row address signal RADD. To this end, the row decoder 140 may connect the global lines GSSL, GWN0 to GWLn, and GDSL with the local lines DSL, WL0 to WLn, and SSL of the selected memory block 110 MB in response to the row address signal RADD.

The voltage supply circuit formed by the voltage generating circuit 130 and the row decoder 140 may supply voltages to the local lines DSL, WL0 to WLn, and SSL and the common source line CSL so that a program operation may be performed using an HCI technique. A specific operation will be described later.

The page buffer groups 150 may include a plurality of page buffers PB0 to PBk connected to the bit lines BLe0 and BLo0 to BLek and Blok, respectively. The page buffers PB0 to PBk of the page buffer group 150 may be respectively connected to pairs of even bit lines and odd bit lines. The page buffers PB0 to PBk of the page buffer group 150 may selectively precharge the bit lines BLe0 to BLek or BLo0 to Blok depending on input data to store the input data in the memory cells Ce00 to Ce0k or Co00 to Co0k in response to PB control signals PB_SIGNALS of the control circuit 120. In addition, the page buffers PB0 to PBk may sense voltages of the bit lines BLe0 to BLek or BLo0 to Blok to read data from the memory cells Ce00 to Ce0k or Co00 to Co0k or perform a verification operation in response to PB control signals PB_SIGNALS of the control circuit 120.

For example, during the program operation, the page buffer group 150 may apply a program prohibition voltage to a bit line of an unselected memory string including a program prohibition cell and apply a program permission voltage to a bit line of a selected memory string including a program permission cell.

The column selection circuit 160 may select the page buffers PB0 to PBk included in the page buffer group 150 in response to a column address output by the control circuit 120. That is, the column selection circuit 160 may sequentially transmit data to be stored in memory cells to the page buffers PB0 to PBk in response to a column address CADD during a program operation. Also, the column selection circuit 160 may sequentially select the page buffers PB0 to PBk in response to the column address CADD to externally output data of memory cells, which is latched in the page buffers PB0 to PBk, during a read operation.

The I/O circuit 170 may transmit data inputted externally to the column selection circuit 160 under the control of the control circuit 120 to store the data in the memory cells during a program operation. Also, during a read operation, the I/O circuit 170 may externally output data transmitted from the page buffers PB0 to PBk of the page buffer group 150 through the column selection circuit 160.

Hereinafter, a program operation performed in a semiconductor memory device using an HCI technique according to an exemplary embodiment of the present invention will be described.

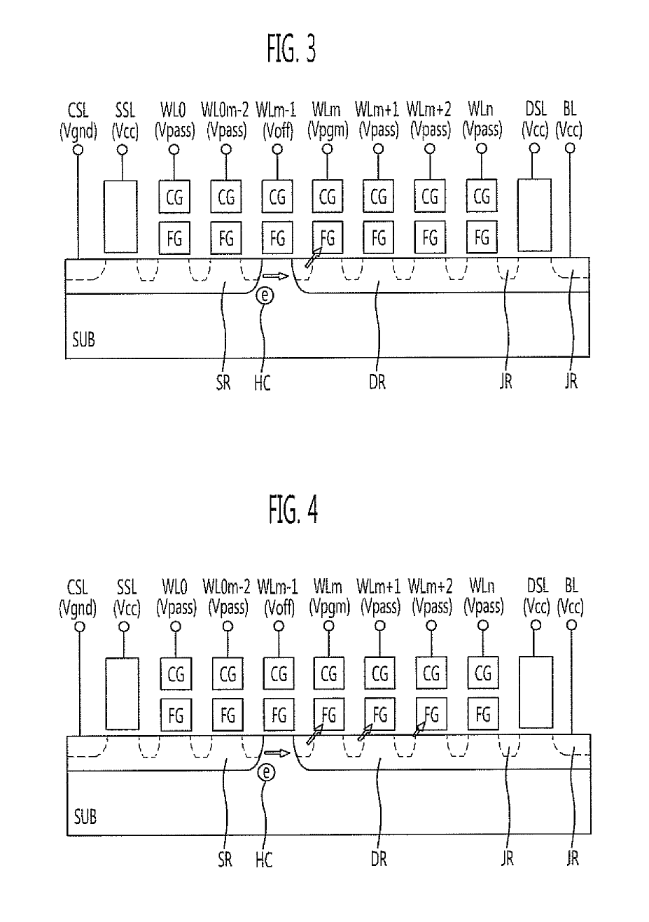

FIGS. 3 through 6 are diagrams illustrating a program operation performed using an HCI technique in the semiconductor memory device of FIG. 1, according to an exemplary embodiment of the present invention. FIG. 7 is a signal waveform diagram illustrating a method of operating a semiconductor memory device according to an exemplary embodiment of the present invention.

Referring to FIGS. 1 through 3, the source selection line SSL and the drain selection line DSL may be disposed parallel to each other on a substrate SUB having a p-well (not shown), and cell gates including floating gates FG and control gates CG may be formed between selection lines SSL and DSL. The corresponding control gates CG included in different memory strings may be connected and form the word lines WL0 to WLn. Junction regions JR may be formed in the substrate SUB between the word lines WL0 to WLn (or between cell gates). A junction region JR formed at one side of the drain selection line DSL may be connected to a bit line BL, and a junction region JR formed at one side of the source selection line SSL may be connected to the common source line CSL.

During a program operation, the power supply circuit 130 and 140 may apply selection voltages having a first level to the selection lines SSL and DSL, apply a ground voltage Vgnd to the common source line CSL, apply a program voltage Vpgm to a selected word line WLm, apply a switch voltage Voff to a switch word line WLm−1 connected to a switch cell, and apply a pass voltage Vpass for turning on memory cells to the remaining word lines WL0 to WLm−2 and WLm+1 to WLn. Here, the switch word line WLm−1 may be adjacent to the selected word line WLm between the selected word line WLm and the source selection line SSL. Also, the switch voltage Voff may be elevated from 0 V or a level lower than 0 V to a second level, which may be higher than a level of a power supply voltage and equal to or lower than a level of the pass voltage Vpass. A bit line voltage having a third level may be applied to the bit line BL by the page buffer group 150. Each of selection voltages and a bit line voltage may be a power supply voltage Vcc.

Thus, during an initial period, the switch cell of the switch word line WLm−1 may be turned off, junction regions JP disposed between the bit line BL and the switch word line WLm−1 may be electrically connected to channels formed due to the pass voltage Vpass applied to the word lines WLm to WLn to form a drain region DR connected to the bit line BL. A power supply voltage Vcc may be applied through the bit line BL to the drain region DR. Also, junction regions JP disposed between the common source line CSL and the switch word line WLm−1 may be electrically connected to channels formed due to the pass voltage Vpass applied to the word lines WL0 to WLm−2 to form a source region SR connected to the common source line CSL. A ground voltage Vgnd may be applied through the common source line CSL to the source region SR.

A strong lateral field may be formed between the source region SR and the drain region DR. In this state, the switch voltage Voff applied to the switch word line WLm−1 starts to rise, and hot electrons HC may be generated from part of a current generated when the switch voltage Voff is near a threshold voltage of the switch cell. The hot electrons HC may be injected to a floating gate of the selected word line WLm due to a vertical field formed by the program voltage Vpgm applied to the selected word line WLm.

As described above, when a program operation is performed using an HCI technique, the program operation may be performed at a lower program voltage than in the conventional case.

Referring to FIG. 4, a pass voltage Vpass may be applied to word lines WLm+1 and WLm+2 disposed adjacent to the selected word line WLm. Due to a vertical electric field formed by the pass voltage Vpass, some of hot electrons HC may be also injected to a floating gate FG of memory cells of the word lines WLm+1 and WLm+2. Thus, pass disturbance may occur so that threshold voltages of memory cells of unselected word lines WLm+1 and WLm+2 are elevated.

In addition, with an increase in integration density, an interval between word lines narrows. Therefore, a voltage difference increasing between the switch word line WLm−1 and the selected word line WLm may cause an error. For example, when the switch cell is in an erased state, a threshold voltage of the switch cell may be about −5 V. To maintain the switch cell in an off state during the initial period, a switch voltage Voff of at least 6 V is to be applied to the switch word line WLm−1 so that hot electrons HC may be smoothly injected. Also, a program voltage of about 12 V to about 15 V is to be applied to the selected word line WLm to elevate a threshold voltage of the memory cell of the selected word line WLm to at least about 3 V to about 4 V or higher. As a result, a voltage difference of about 20 V or higher may occur between the switch word line WLm−1 and the selected word line WLm. As an interval between word lines decreases, breakdown may occur.

Referring to FIGS. 1, 5, and 7, the voltage supply circuit 130 and 140 may apply a pass voltage Vpass2 to an unselected word line WLm+1 disposed adjacent to the selected word line WLm and opposite to the switch word line WLm−1 at a lower level than a pass voltage Vpass1 applied to other unselected word lines. Next, a pass voltage Vpass3 higher than the pass voltage Vpass2 and lower than the pass voltage Vpass1 may be applied to the unselected word line WLm+2 disposed adjacent to the unselected word line WLm+1.

As described above, with the application of the pass voltages Vpass2 and Vpass3, the vertical field formed at the unselected word line WLm+1 may weaken, thereby preventing injection of hot electrons HC. Also, since the hot electrons HC are prevented from being injected at the unselected wore line WLm+1, the same normal pass voltage Vpass1 may be applied or the pass voltage Vpass3 lower than the pass voltage Vpass1 and higher than the pass voltage Vpass2 may be applied to the unselected word line WLm+2.

Referring to FIGS. 1, 6, and 7, a word line WLm−2 that is most adjacent to the selected word line WLm next to the word line WLm−1 between the source selection line SSL and the selected word lien WLm may be defined as a switch word line configured to generate hot electrons. Also, a pass voltage Vpass4 having a lower level than the normal pass voltage Vpass1 may be applied to the word line WLm−1 between the switch word line WLm−2 and the selected word line WLm. That is, to prevent injection of hot electrons into the word line WLm−1 due to a vertical field, a pass voltage Vpass4 having a low level may be applied to the word line WLm−1. Since the word line WLm−1 is a word line most adjacent to a region in which hot electrons are generated, the pass voltage Vpass4 may be applied at a lower level than other pass voltages Vpass1 to Vpass3.

The unselected word line WLm−1 may function as a buffer word line to reduce stress caused by a high voltage difference between the switch word line WLm−2 and the selected word line WLm. That is, since a program voltage Vpgm may be applied to the selected word line WLm and a pass voltage Vpass4 is applied to the word line WLm−1, a voltage difference between the selected word line WLm and the word line WLm−1 may not be high. Also, even if a negative voltage is applied to the switch word line WLm−2, since a pass voltage Vpass4 having a low level is applied to the word line WLm−1, a voltage difference between the switch word line WLm−2 and the word line WLm−1 may not be high.

Therefore, since voltage differences among the word lines WLm−2, WLm−1, and WLm are not high, the occurrence of breakdown may be inhibited, and an interval between word lines may be further reduced to increase integration density.

The above-described pass voltages Vpass1 to Vpass4 may be supplied from the voltage supply circuit 130 and 140 under the control of the control circuit 120 at a higher level than an uppermost program level of memory cells.

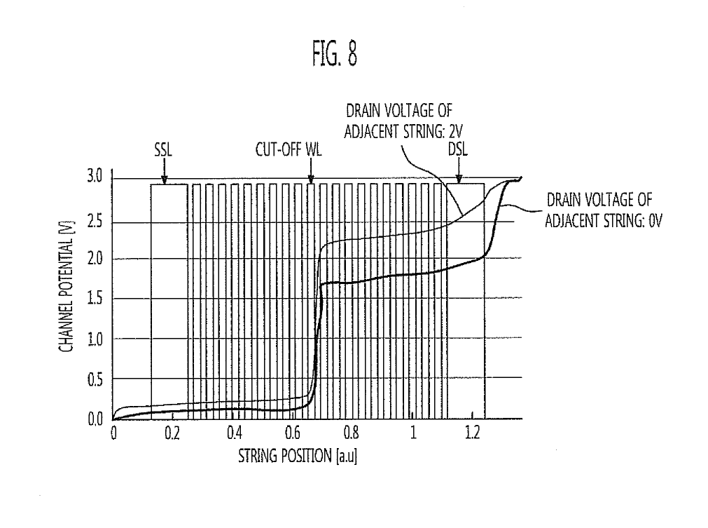

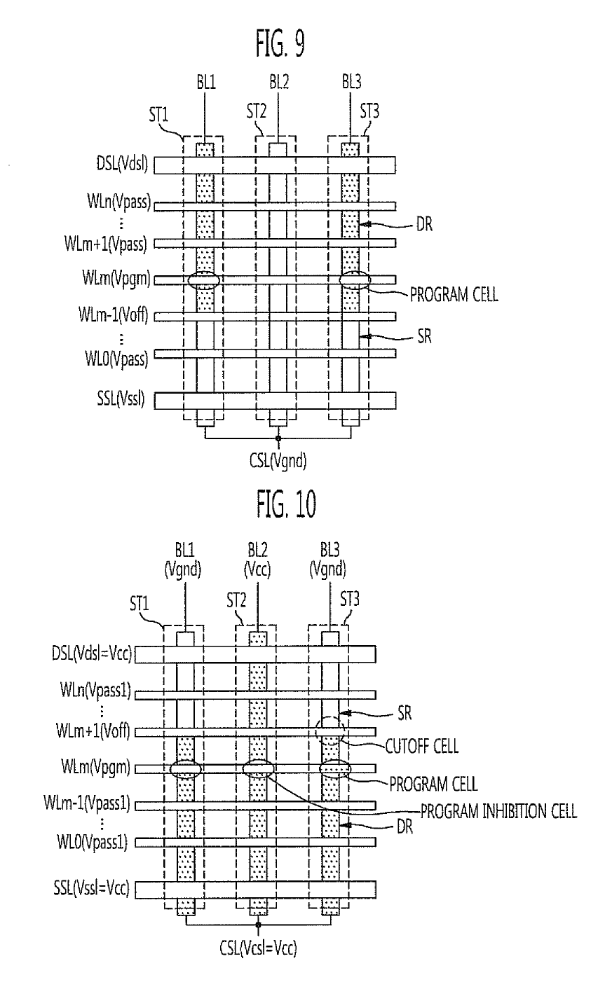

FIG. 8 is a graph illustrating a variation in the voltage of a drain region during a program operation using an HCI technique according to an exemplary embodiment of the present invention, and FIG. 9 is a diagram illustrating a program operation of applying a ground voltage to a channel region of a program prohibition string in FIG. 8.

Referring to FIGS. 8 and 9, during the program operation, when a power supply voltage is applied to bit lines BL1 and BL3 of selected memory strings ST1 and ST3 and the power supply voltage is applied to a bit line BL2 of an unselected memory string ST2 disposed adjacent to the selected memory strings ST1 and ST3, there may be no voltage difference between drain regions DR of the selected memory strings ST1 and ST3 and a drain region DR of the unselected memory string ST2. Accordingly, a leakage current may not occur between drain regions, and a voltage of the drain regions may not be dropped.

However, when a power supply voltage is applied to the drain regions DR of the selected memory strings ST1 and ST3 through the bit lines BL1 and BL3 and a ground voltage is applied from the bit line BL2 to the drain region DR of the unselected memory string ST2 disposed adjacent to the selected memory strings ST1 and ST3, a voltage difference may occur between the drain regions DR of the memory strings ST1/ST2 or ST2/ST3. In this state, when a leakage current occurs between the memory strings ST1/ST2 or ST2/ST3, voltages of the drain regions DR of the selected memory strings ST1 and ST3 may be dropped. When the voltages of the drain regions DR of the selected memory strings ST1 and ST3 are dropped, hot electrons may not be efficiently generated in switch cells of the switch word lines WLm−1 so that program cells may not properly perform program operations.

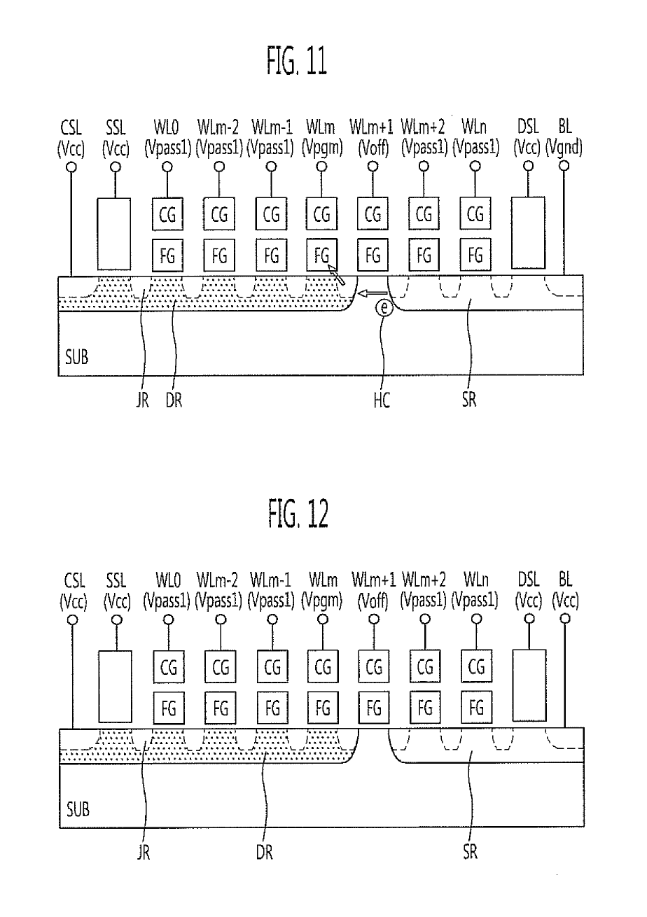

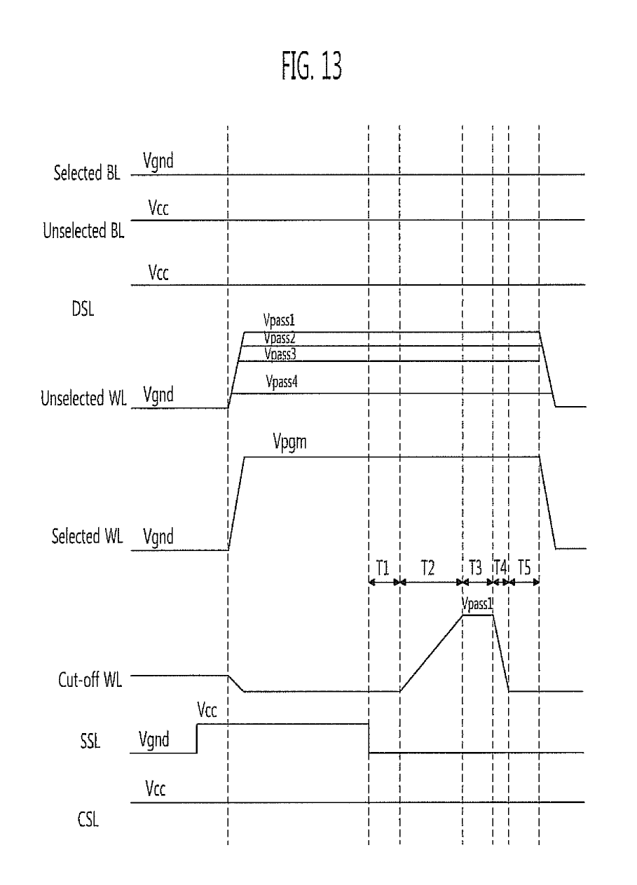

FIG. 10 is a diagram of a program operation performed using an HCI technique in the semiconductor memory device of FIG. 1, according to another embodiment of the present invention. FIG. 11 is a cross-sectional view of a selected memory string configured to cause HCI out of memory strings shown in FIG. 10, and FIG. 12 is a cross-sectional view of an unselected memory string configured not to generate HCI out of the memory strings shown in FIG. 10. FIG. 13 is a signal waveform diagram illustrating a method of operating a semiconductor memory device according to another exemplary embodiment of the present invention.

The peripheral circuits 120 to 170 shown in FIG. 1 may be configured to apply a program voltage, pass voltages, a switch voltage, a source selection voltage, a drain selection voltage, a common source voltage, and a bit line voltage, which are described below, to a selected word line, unselected word lines, a switch word line, a source selection line, a drain selection line, a common source line, and bit lines. A program operation of a selected cell may be greatly divided into a setup period and a program period.

### Setup Period

Referring to FIGS. 10, 11, and 13, a program permission voltage Vgnd may be applied to bit lines BL1 and BL3 of selected memory strings ST1 and ST3 including program cells.

Referring to FIGS. 10, 12, and 13, a program prohibition voltage Vcc may be applied to a bit line BL2 of an unselected memory string ST2 including a program prohibition cell. When memory cells included in an even page perform a program operation, an even memory string including the program prohibition cell or odd memory strings including memory cells of an odd page may be included in the unselected memory string ST2.

Referring to FIGS. 10 through 13, a power supply voltage Vcc may be applied as selection voltages to the selection lines DSL and SSL, and a power supply voltage Vcc may be applied to the common source line CSL.

In addition, a program voltage Vpgm of about 12 V to about 15 V may be applied to the selected word line WLm, a switch voltage Voff may be applied to the switch word line WLm+1, and a pass voltage Vpass may be applied to the remaining unselected word lines WL0 to WLm−1 and WLm+2 to WLn. Here, a word line disposed adjacent to the selected word line WLm and between the selected word line WLm and the drain selection line DSL may become a switch word line WLm+1. That is, a memory cell disposed adjacent to a selected cell and between the selected cell and a drain selection transistor may become a switch cell for generating hot electrons.

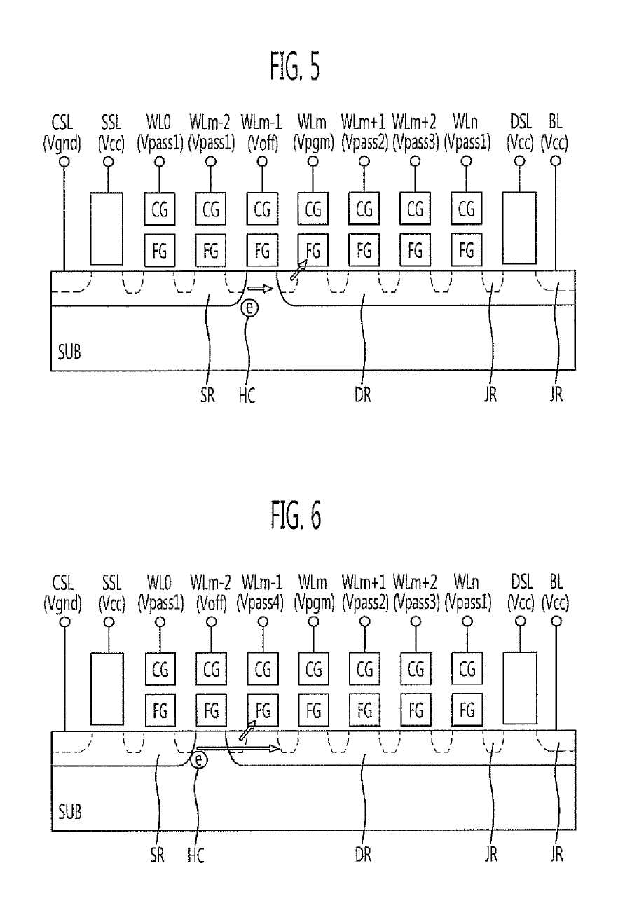

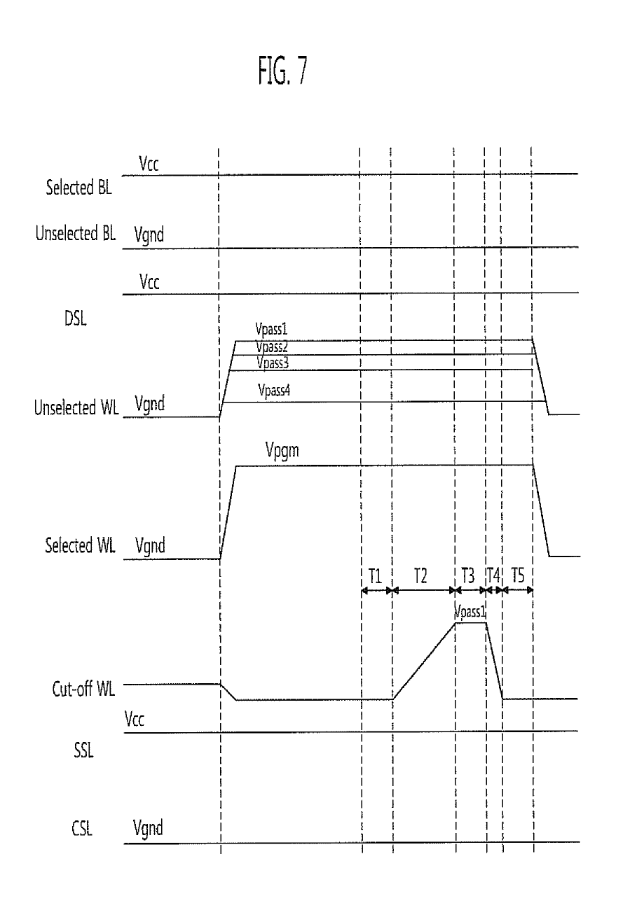

Meanwhile, as described with reference to FIG. 5 or FIG. 6, a plurality of pass voltages Vpass1 to Vpass4 may be applied to the remaining unselected word lines WL0 to WLm−1 and WLm+2 to WLn. Hereinafter, a case in which only one kind of pass voltage Vpass1 is applied to the unselected word lines WL0 to WLm−1 and WLm+2 to WLn will be described as an example for brevity.

Referring to FIGS. 10, 11, and 13, with the application of the above-described voltages, in the selected memory strings ST1 and ST3 including program cells, during an initial period, the switch cell of the switch word line WLm−1 may be turned off, and junction regions JP disposed between the common source line CSL and the switch word line WLm+1 may be electrically connected to channels formed due to the pass voltage Vpass and the program voltage Vpgm applied to the word lines WL0 to WLm to form a drain region DR connected to the common source line CSL. A power supply voltage Vcc may be applied through the common source line CSL to the drain region DR. Also, junction regions JP disposed between the bit lines BL1 and BL3 and the switch word line WLm+1 may be electrically connected to channels formed due to the pass voltage Vpass applied to the word lines WL+2 to WLn to form a source region SR connected to each of the bit lines BL1 and BL3. A ground voltage Vgnd may be applied through the bit lines BL1 and BL3 to the source region SR.

Since the drain region DR has a high voltage and the source region SR has a low voltage in the selected memory strings ST1 and ST3, a lateral field may be formed between the drain region DR and the source region SR.

Referring to FIGS. 10, 12, and 13, a power supply voltage Vcc may be applied through the bit line BL2 and the common source line CSL to the drain and source regions DR and SR of the unselected memory string ST2 including a program prohibition cell. Accordingly, since there is no voltage difference between the drain and source regions DR and SR in the unselected memory string ST2, no lateral field may be formed.

Furthermore, since a power supply voltage is applied to both the drain regions DR of the selected memory strings ST1 and ST3 and the drain region DR of the unselected memory string ST2, there may be no voltage difference therebetween. Accordingly, voltages applied to the drain regions DR of the selected memory strings ST1 and ST3 may not be lowered.

Thus, a setup period of precharging channel regions of memory cells included in the unselected memory string ST2 and precharging channel regions of a selected cell and memory cells interposed between the selected cell and a source selection transistor, among memory cells included in the selected memory strings ST1 and ST3, may be finished to perform a program operation.

### Program Period

Referring to FIGS. 10 through 13, a selection voltage applied to the source selection line SSL may be reduced from a power supply voltage Vcc to a ground voltage Vgnd, and a source selection transistor connected to the source selection line SSL may be turned off. Thus, drain regions DR of the selected memory strings ST1 and ST3 may be in a floating state. When the pass voltage Vpass1 and the program voltage Vpgm are applied, a voltage of the drain regions DR may be further boosted due to channel boosting. Therefore, before the selection voltage is decreased, the source selection transistor connected to the source selection line SSL may be turned off due to channel boosting.

After a first period T1 from the drop of the source selection voltage Vss1, the switch voltage Voff may start to rise. Here, to minimize current flowing through a memory string, the switch voltage Voff may be elevated right after the selection transistor is turned off. For example, after a time of about 10 μsec or less elapses since the selection transistor is turned off, the switch voltage Voff may be elevated. That is, the first period T1 may be set to about 0 sec to about 10 μsec.

Meanwhile, the switch voltage Voff may be applied at a level about 1 V lower than a threshold voltage of an erased switch cell during an initial period. For example, a switch voltage Voff of about −4 V to about −8 V may be applied. The switch voltage Voff may be elevated to a target level during a second period T2. The second period may be set to about 2 μsec to about 10 μsec. Also, to fully turn on the switch cell (i.e., to fully form a channel in the switch cell), the switch voltage Voff may be elevated to the normal pass voltage Vpass1 or a voltage of about 3 V to about 7 V.

When the switch voltage Voff is elevated to almost a threshold voltage (e.g., a threshold voltage±1 V) of the switch cell, hot electrons may be generated and transported, and injected into a floating gate of a program cell due to a program voltage Vpgm applied to the selected word line WLm. In this case, since hot electrons are not generated in the unselected memory string ST2, electrons may not be injected into a floating gate of a program prohibition cell.

Thereafter, the program voltage Vpgm, the pass voltage Vpass1, and the switch voltage Voff may be discharged. Specifically, the switch voltage Voff may be elevated to a target level, maintained at the target level during a third period T3, and discharged during a fourth period T4. Also, the program voltage Vpgm and the pass voltage Vpass may be discharged during a fifth period T5. The switch voltage Voff, the program voltage Vpgm, and the pass voltage Vpass may be discharged during the same period.

As a result, a program period may be finished.

As described above, a program operation may be performed using an HCI technique so that a program voltage may be reduced, and word line breakdown and charge loss may be prevented from being caused by a voltage difference between gates.

Furthermore, channel regions of memory cells included in an unselected memory string may be precharged, thereby enabling smooth generation of hot electrons in a selected memory string and improving operating characteristics.

According to embodiments of the present invention, a program operation may be performed using an HCI technique so that a program voltage applied to a word line (or control gate) may be reduced as compared with a program operation using a Fowler-Nordheim (FN) tunneling technique, and word line breakdown and charge loss, which may be caused by a voltage difference between gates, may be prevented.

In addition, when a program operation is performed using an HCI technique, a voltage applied to a selection transistor may be controlled so that consumed current may be reduced to the same level as when a program operation is performed using FN tunneling, and generation of heat and power consumption may be prevented.

In the drawings and specification, there have been disclosed exemplary embodiments of the invention, which are exemplary only. Therefore, it will be apparent to those of ordinary skill in the art that various changes and modifications in form and details may be made therein without departing from the spirit and scope of the present invention as defined by the following claims.

What is claimed is:

1. A method of operating a semiconductor memory device, comprising:
supplying first and second voltages to a memory string through a bit line and a common source line, respectively, by turning on drain and source selection transistors;
applying a program voltage to a selected word line of word lines coupled to memory cells and a switch voltage to a switch word line disposed between a selected word line and the common source line;
applying a first pass voltage to first unselected word lines disposed between the switch word line and the common source line and between the selected word line and the bit line and a second pass voltage lower than the first pass voltage to a second unselected word line between the switch word line and the selected word line; and
elevating the switch voltage to generate hot electrons and inject the hot electrons into a selected memory cell of the selected word line, among the memory cells.

2. The method of claim 1, wherein a third pass voltage lower than the first pass voltage and higher than the second pass voltage is applied to a third unselected line disposed adjacent to the selected word line and between the selected word line and the bit line, out of the first unselected word lines.

3. The method of claim 2, wherein a fourth pass voltage lower than the first pass voltage and higher than the third pass voltage is applied to a fourth unselected line disposed adjacent to the third unselected line and between the third unselected line and the bit line, out of the first unselected lines.

4. The method of claim 1, further comprising turning off the drain selection transistor before the elevating of the switch voltage.

5. The method of claim 1, wherein the switch voltage is elevated from a negative voltage to the first pass voltage.

6. The method of claim 1, wherein the first and second voltages include a power supply voltage and a ground voltage, respectively.

7. A method of operating a semiconductor memory device, comprising:
applying a first voltage to selected bit lines of bit lines and a second voltage to unselected bit lines other than the selected bit lines and a common source line;
turning on drain and source selection transistors;
applying a program voltage to a selected word line of word lines coupled to the memory cells and a switch voltage to a switch word line disposed between the selected word line and the bit line;
applying a first pass voltage to first unselected word lines disposed between the switch word line and the bit line and between the selected word line and the common source line; and
elevating the switch voltage to generate hot electrons and inject the hot electrons to a selected memory cell of the selected word line, among the memory cell, to program the selected cell.

8. The method of claim 7, wherein the applying of the first pass voltage comprises applying a second pass voltage lower than the first pass voltage to a second unselected word line between the switch word line and the selected word line.

9. The method of claim 8, wherein a third pass voltage lower than the first pass voltage and higher than the second pass voltage is applied to a third unselected line disposed adjacent to the selected word line and between the selected word line and the common source line, out of the first unselected word lines.

10. The method of claim 9, wherein a fourth pass voltage lower than the first pass voltage and higher than the third pass voltage is applied to a fourth unselected line disposed adjacent to the third unselected line and between the third unselected line and the common source line, out of the first unselected lines.

11. The method of any one of claim 7, further comprising turning off the source selection transistors before the elevating of the switch voltage.

12. The method of any one of claim 7, wherein the switch voltage is elevated from a negative voltage to the first pass voltage.

13. The method of claim 7, wherein the first and second voltages include a ground voltage and a power supply voltage, respectively.

14. A semiconductor memory device comprising:
a plurality of memory strings connected between a common source line and respective bit lines and each including a drain selection transistor and a source selection transistor coupled to the bit line and the common source line, respectively, and a plurality of memory cells having control gates connected to respective word lines between the drain and source selection transistors; and
a peripheral circuit configured to perform a first operation of applying a first voltage to selected bit lines of the bit lines and a second voltage to unselected bit lines other than the selected bit lines and the common source line and turning on the drain and source selection transistors, a second operation of applying a program voltage to a selected word line of the word lines, a switch voltage to a switch word line disposed adjacent to the selected word line, a first pass voltage to first unselected word lines other than the selected word line and the switch word line, and a third operation of elevating the switch voltage to generate hot electrons and inject the hot electrons to a selected cell of the selected word line, among the memory cells.

15. The device of claim 14, wherein the first unselected word lines include a second unselected word line disposed between the selected word line and the switched word line, a third unselected word line disposed adjacent to the selected word line and opposite to the second unselected word line, and a fourth unselected word line disposed adjacent to the third unselected word line and opposite to the selected word line,
wherein a second pass voltage lower than the first pass voltage is applied to the second unselected word line, a third pass voltage lower than the first pass voltage and higher than the second pass voltage is applied to the third unselected word line, and a fourth pass voltage lower than the first pass voltage and higher than the third pass voltage is applied to the fourth unselected word line.

16. The device of claim 14, wherein the peripheral circuit is configured to turn off the drain or source selection transistors before performing the third operation.

17. The device of any one of claim 12, wherein the peripheral circuit is configured to elevate the switch voltage from a negative voltage to the first pass voltage.

18. The method of claim 17, wherein the first voltage includes one of a ground voltage and a power supply voltage and the second voltage includes the other.
